(19) United States
(12) Patent Application Publication
(10) Pub. No.: US 2025/0231222 A1
(43) Pub. Date: Jul. 17, 2025

(54) MEASURING DEVICE FOR ELECTRICAL QUANTITIES

(71) Applicant: TQ-Systems GmbH, Seefeld (DE)

(72) Inventors: Raik MELZER, Chemnitz (DE); Daniel KOETHE, Chemnitz (DE)

(21) Appl. No.: 19/016,524

(22) Filed: Jan. 10, 2025

(30) Foreign Application Priority Data
Jan. 11, 2024 (DE) 10 2024 100 779.6

(51) Int. Cl. G01R 15/04; G01R 15/18

(52) U.S. Cl. CPC G01R 15/04; G01R 15/18

(57) ABSTRACT

A measuring device for has a housing, a measuring circuit board, and a communication circuit board. The measuring circuit board has a voltage connection, a voltage divider, a CT connection for connecting an external current transformer, a measuring chip connected to the voltage divider and the CT connection for determining electrical quantities and outputting as measurement data to a first part of a plug connector. The communication circuit board is connected to a second part of the plug connector, which together with the first part connects the communication circuit board and the measuring circuit board, a data communication chip connected to the second part and electrically isolated to receive the measurement data from the measuring chip, where a galvanic isolation between the measuring chip and the data communication chip is provided on the communication circuit board, a data connection connected to the data communication chip and a user interface.

### CROSS REFERENCE TO RELATED APPLICATIONS

This application claims priority to German Application No. 10 2024 100 779.6, filed Jan. 11, 2024, the contents of which are incorporated by reference herein.

### FIELD OF THE INVENTION

The invention relates to a measuring device for electrical quantities with one or more external current transformers. The measuring device has a compact configuration, is also referred to as an energy meter and is intended in particular for mounting on a top-hat rail. Moreover, a further invention relates to an electronic device with an interlocked two-part latching housing. Moreover, a further invention relates to an electronic circuit arrangement for voltage/current measurement in such a measuring device.

### BACKGROUND

Measuring devices that use external current transformers to measure electrical quantities, such as current, voltage, power, power factor and/or frequency, are known. The target direction of the embodiments disclosed herein lies in the application to use such measuring devices under limited spatial conditions such as, e. g., in a control cabinet that is already almost fully occupied. Moreover, a further target direction is to enable use in various regional areas of use with their own regulatory requirements.

The desired functionality of such electronic devices is implemented using electronic components such as AC/DC power supplies, DC/DC converters, DC/DC isolators, measuring ICs (also referred to as measuring chips), computing units, resistors, capacitors, switches, and connections. The electronic components are usually arranged on a circuit board and together form a measuring system. Specific components process the electrical measuring quantities appropriately and supply the measuring chip with the measuring quantities, for example. For example, a voltage to be measured is processed and fed to the measuring IC. Electrical parameters to be measured are provided inter alia by the connected current transformers. The electrical quantities determined by the electronic device are output and can be used, for example, to control a plurality of current-generating and/or current-consuming systems.

An objective of the concepts disclosed herein relates to the provision of such an electrical device as a compact device that can be used in particular for cost-effective current metering such as for measuring the usage data of individual consumers. The electrical devices may be usable in energy flow control by means of an energy manager and/or in the context of decentralized measurement of a plurality of consumers.

The concepts disclosed herein may be directed to improving, at least in part, one or more aspects that relate to the versatile use of electronic devices. For example, an aspect of this disclosure is based on an objective of keeping the space requirement as low as possible (compact structure). Further aspects of this disclosure are based on objectives of fulfilling safety requirements (safe structure) and/or enabling cost-effective implementation (cost-effective structure).

### SUMMARY

At least one of these objectives may be addressed by an electronic measuring device in accordance with this disclosure.

In an aspect, a measuring device for electrical quantities comprises a housing, a measuring circuit board and a communication circuit board, which are arranged offset on top of each other in the housing, wherein the measuring circuit board is equipped with a voltage connection, a voltage divider electrically connected to the voltage connection, at least one first CT connection for connecting at least one external current transformer, a first measuring chip, which is electrically connected to the voltage divider and the first CT connection, for determining the electrical quantities and for outputting the electrical quantities as measurement data to a first part of a plug connector, and wherein the communication circuit board is equipped with a second part of the plug connector which, together with the first part, causes an electrical plug connection between the communication circuit board and the measuring circuit board, a data communication chip, which is electrically connected to the second part and galvanically isolated in order to receive the measurement data from the first measuring chip, wherein a galvanic isolation is provided between the first measuring chip and the data communication chip on the communication circuit board, at least one data connection electrically connected to the data communication chip and at least one user interface electrically connected to the data communication chip.

In a further aspect, an electrical device, in particular for measuring electrical quantities, comprises an electrical circuit arrangement, in particular for determining and outputting the electrical quantities, which comprises a voltage connection and at least one user interface and is arranged in a housing, the housing comprising a first shell and a second shell as a two-part housing and having a latching connection for mechanically connecting the first shell to the second shell, wherein the latching connection is formed by at least one latching hook and at least one latching region on correspondingly the first shell and the second shell. The electrical device further comprises a formed component arranged in the housing, the formed component configured as at least one blocking element which, in the assembled state, is arranged relative to the latching hook such that a disengagement of the latching connection, in particular deformation of the latching hook in the direction of an interior of the housing, is counteracted.

In a further aspect, a measuring device for electrical quantities comprises an electrical circuit arrangement, wherein the electrical circuit arrangement comprises a voltage connection, a voltage divider electrically connected to the voltage connection, a first CT connection for connecting at least one external current transformer and a second CT connection for connecting at least one external current transformer, a first measuring chip electrically connected to the voltage divider and the first CT connection for determining and outputting the electrical quantities as measurement data for the at least one external current transformer connected to the first CT connection, a second measuring chip electrically connected to the voltage divider and the second CT connection for determining and outputting the electrical quantities as measurement data for the at least one external current transformer connected to the second CT connection, a data communication chip, which is configured to receive, process and output the measurement data from the first measuring chip and from the second measuring chip. The voltage divider is configured to output voltages to the first measuring chip and the second measuring chip and comprises a voltage input for receiving an input voltage from the voltage connection, for each of the measuring chips, a voltage output for outputting a reduced voltage to the respective measuring chip, a resistor series section electrically connected to the voltage input and comprising a plurality of series-connected resistors contributing to the voltage drop for each of the measuring chips, and a parallel circuit section electrically connected to a last resistor of the resistors of the resistor series section and comprising, for each voltage output, a first resistor section comprising at least one resistor, extending the series-connected resistors of the resistor series section and being electrically connected to a respective voltage output, a second resistor section comprising at least one resistor and electrically connecting the respective voltage output and a neutral conductor, and a capacitor section comprising at least one capacitor and electrically connecting the respective voltage output and the neutral conductor.

The measuring devices and the electrical device can be further embodied as summarized below.

In some embodiments of the measuring/electrical device, the measuring circuit board can also be equipped with an AC/DC power supply unit that is electrically connected to the voltage connection, for supplying voltage to the first measuring chip, is electrically connected to the first measuring chip, in particular via a linear regulator, for supplying voltage to the data communication chip, is electrically connected to the data communication chip (43) in a galvanically isolated manner via the electrical plug connection and a DC isolation element arranged on the communication circuit board, in particular via a DC/DC element for voltage reduction.

In some embodiments of the measuring/electrical device, the at least one data connection can comprise an Ethernet connection and/or an RS485 connection and/or the at least one user interface can comprise an LED display and/or a push button.

In some embodiments of the measuring/electrical device, the housing can comprise a first shell and a second shell as a two-part housing, wherein the measuring circuit board can be mounted in the first shell and the communication circuit board can be mounted in the second shell, in each case in particular via a screw or latching connection. Furthermore, the plug connector can be achieved in particular by assembling the first shell and the second shell to form the housing. Furthermore, the housing can have a latching connection for mechanically connecting the first shell to the second shell and/or can have openings, in particular in the first shell, for the voltage connection and/or the at least one first CT connection, and/or openings, in particular in the second shell, for the at least one data connection and the at least one user interface, wherein the user interface is made accessible to a user in particular via an optical fiber and/or plunger element arranged between the communication circuit board and the second shell.

In some embodiments of the measuring/electrical device, the housing can comprise a first shell and a second shell as a two-part housing and have a latching connection for mechanically connecting the first shell to the second shell, wherein the latching connection is formed by at least one latching hook and at least one latching region, in particular an opening, on respectively the first shell and the second shell. The measuring device can further comprise a formed component arranged between the measuring circuit board and the communication circuit board and having at least one blocking element, wherein the at least one blocking element is arranged in the assembled state with respect to a latching hook such that a disengagement of the latching connection, in particular deformation of the associated latching hook in the direction of an interior of the housing, is counteracted, and in particular a disengagement is prevented. Furthermore, the latching connection can have latching hooks arranged on opposite sides of the housing and the formed component can be configured such that it counteracts a disengagement of at least one of the latching hooks on each side of the housing.

In some embodiments of the measuring/electrical device, the formed component can be configured such that it provides a minimum distance between the measuring circuit board and the communication circuit board in the assembled state, and in particular ensures the minimum distance, in particular even if one or both of the measuring circuit board and the communication circuit board are not connected to the respective first and second shells. Alternatively or additionally, the formed component can be made of an electrically insulating material.

In some embodiments of the measuring/electrical device, the formed component can comprise at least one stand, which is arranged in particular in the assembled state in a non-equipped area of the measuring circuit board and the length of which determines in particular a position of the at least one blocking element inside the housing, and in particular the minimum distance between the measuring circuit board and the communication circuit board, and/or a flat-shaped structural section, which positions the at least one blocking element spatially with respect to the at least one latching hook, and/or wherein the at least one blocking element is arranged in the assembled state in a non-equipped area of the communication circuit board.

In some embodiments of the measuring/electrical device, the formed component and at least one of the first shell and the second shell can form a guide system which is designed for positioning the formed component during assembly of the measuring device and/or for holding the formed component in the assembled state, wherein the guide system comprises in particular a guide rail, in particular a groove, on an inner wall of one of the first shell and the second shell or on the formed component and a slide element respectively engaging in the guide rail, in particular in the groove, on the formed component or on the inner wall of one of the first shell and the second shell.

In some embodiments of the measuring/electrical device, the voltage divider can be configured to output reduced voltages to at least two measuring chips for measuring electrical quantities by means of two external current transformers connected to the respective measuring chips. The voltage divider can comprise: a voltage input, in particular for receiving a mains voltage, for each of the at least two measuring chips; a voltage output for outputting one of the reduced voltages to one of the at least two measuring chips; a resistor series section electrically connected to the voltage input, comprising a plurality of series-connected resistors contributing to the voltage drop for each of the at least two measuring chips; and a parallel circuit section electrically connected to a last resistor of the resistors of the resistor series section. The parallel circuit section can comprise: for each of the at least two measuring chips, a resistor extending the series-connected resistors of the resistor series section and electrically connected to a respective voltage output, and for each voltage output, a resistor electrically connecting the respective voltage output and a neutral conductor, and a capacitor electrically connecting the respective voltage output and the neutral conductor.

In some embodiments of the measuring/electrical device, the measuring circuit board can be equipped with a second CT connection for connecting at least one external current transformer, and a second measuring chip, electrically connected to the voltage divider and the second CT connection, for determining the electrical quantities and outputting the electrical quantities to the communication circuit board as measurement data for the at least one external current transformer connected to the second CT connection, and wherein the first measuring chip is electrically connected to a first voltage output and the second measuring chip is electrically connected to a second voltage output.

In some embodiments of the measuring/electrical device, the voltage divider can be configured for reducing an input voltage in a range from 200 V to 1000 V to a measuring voltage range in a range from 0 V to 3 V. Alternatively or additionally, the resistors extending the series-connected resistors of the resistor series section between the respective voltage output and the neutral conductor can provide decoupling between the voltage outputs.

In some embodiments of the measuring/electrical device, the resistors of the resistance series section can form a total resistance in a range from 500 kΩ to 10 MSλ and/or the parallel circuit section can form a resistance in a range from 100Ω to 10 kΩ, so that together with the resistance between the respective voltage output and the neutral conductor, a voltage division is implemented at the respective voltage output. Alternatively or additionally, the resistors of the resistor series section and the resistor between the respective voltage output and the neutral conductor can form an RC low-pass function with the capacitor between the respective voltage output and the neutral conductor for the respective voltage output. Alternatively or additionally, the capacitor between the respective voltage output and the neutral conductor can form a buffer function for the respective voltage output.

In some embodiments, the measuring/electrical device can comprise a further CT connection for connecting a further external current transformer and a further measuring chip, and the parallel circuit section can further comprise a further first resistor section, a further second resistor section and a further capacitor section for a further voltage output associated with the further measuring chip.

The measuring devices proposed herein relate in particular to energy and power measuring devices with a compact design. The functionality of the electronic device can, for example, be divided into (only) two assemblies, in this case arrangements of electronic components on a separate circuit board, wherein the circuit boards are connected with a plug connector. The electronic devices are configured in particular for mounting on a top-hat rail and have, for example, a width of one or two division units (width of a division unit, e. g., 18 mm). With one or two division units in particular, the devices are correspondingly limited in the available construction volume (internal housing volume).

The measuring devices according to the inventive aspects can be used with modularly connectable current transformers, whereby the measuring quantities can be used, for example, to control energy generators and energy consumers. In general, the intended use is that of a real-time measuring device, as used, for example, for energy management with the aim of optimizing self-consumption from the photovoltaic system with storage and, for example, a charging station. In particular, the measuring devices according to the inventive aspects are designed for connecting three or six compact and inexpensive hinged or clamp-on current transformers for current measurement of, e. g., 50 A to 600 A (at 0.333 V or a mA output). Openings of the current transformers are in the range of 10 mm to 40 mm, for example. Furthermore, a so-called sensor bar with, for example, three current transformers arranged next to each other can be used.

The measuring devices according to the inventive aspects can have a wide variety of advantages over the prior art. For example, the following advantages can result:
very compact design in 2 DU
use in the voltage range 200 V-400 V
use in areas of overvoltage category III
use with, e. g., three or six current transformers
evaluation with a very short measuring interval of, e. g., 100 ms
high accuracy of the recorded instantaneous values of current, voltage, power, power factor and/or frequency
very compact design of devices with, for example, several interfaces such as LAN and RS485
galvanically isolated interfaces (RS485/Ethernet)
versatile output of data as Modbus RTU/TCP, SUNSPEC, and customer-specific protocols.

### BRIEF DESCRIPTION OF THE DRAWING

Disclosed herein are concepts that allow at least partial improvement of aspects of the prior art. In particular, further features and their usefulness result from the following description of embodiments with reference to the figures. From the figures:

FIG. 1 shows schematically an exemplary electronic measuring device, in particular for measuring current;

FIG. 2 shows the main components of a housing of the measuring device shown in FIG. 1;

FIG. 3 shows an exemplary implementation of a circuit arrangement of the measuring device shown in FIG. 1;

FIG. 4 shows an exemplary integration of the circuit arrangement shown in FIG. 3 using six current transformers and an energy manager in a block diagram;

FIG. 5 shows an exemplary circuit arrangement for the measuring device shown in FIG. 1 in a block diagram;

FIG. 6 shows an exemplary arrangement of the components of the circuit arrangement for the measuring device shown in FIG. 1 on a circuit board arrangement comprising a measuring circuit board and a communication circuit board;

FIG. 7 shows an exemplary isolation concept for the arrangement of the components of the circuit arrangement according to FIG. 6;

FIG. 8 shows a two-part latching housing;

FIG. 9 shows an exemplary formed component for securing a locked latching connection of the latching housing shown in FIG. 8;

FIG. 10 shows an exemplary arrangement of the formed component from FIG. 8 in a circuit board arrangement according to FIG. 6;

FIG. 11 shows a top view of a measuring circuit board with the formed component arranged as shown in FIG. 10;

FIG. 12 shows the use of voltage dividers for voltage measurement with a measuring chip;

FIG. 13 shows an exemplary setup of a voltage divider for providing a voltage for a measuring chip;

FIG. 14 shows a first exemplary setup of a voltage divider for providing the voltages for two measuring chips; and

FIG. 15 shows a second exemplary setup of a voltage divider for providing voltages to two measuring chips.

### DETAILED DESCRIPTION OF THE PREFERRED EMBODIMENTS

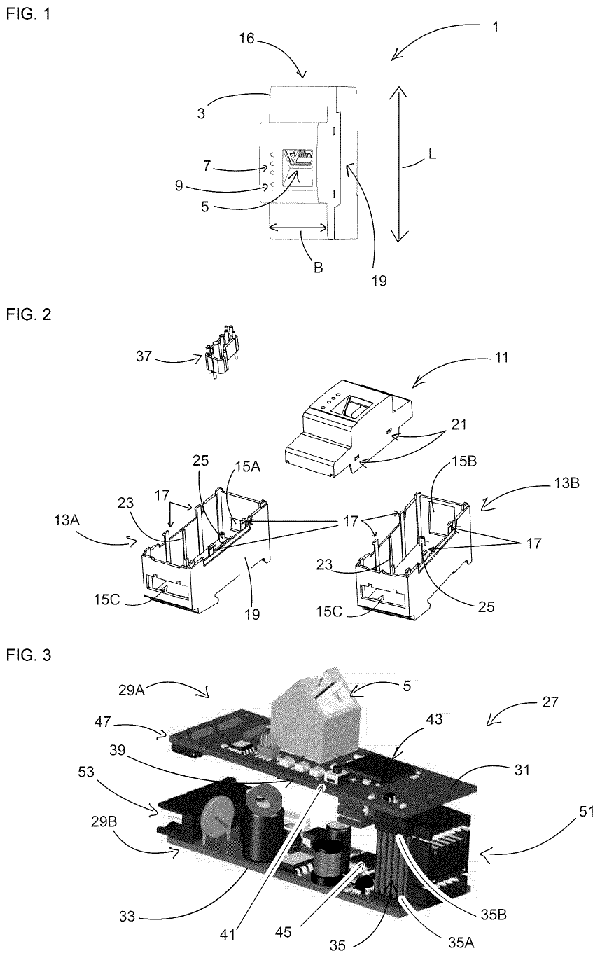

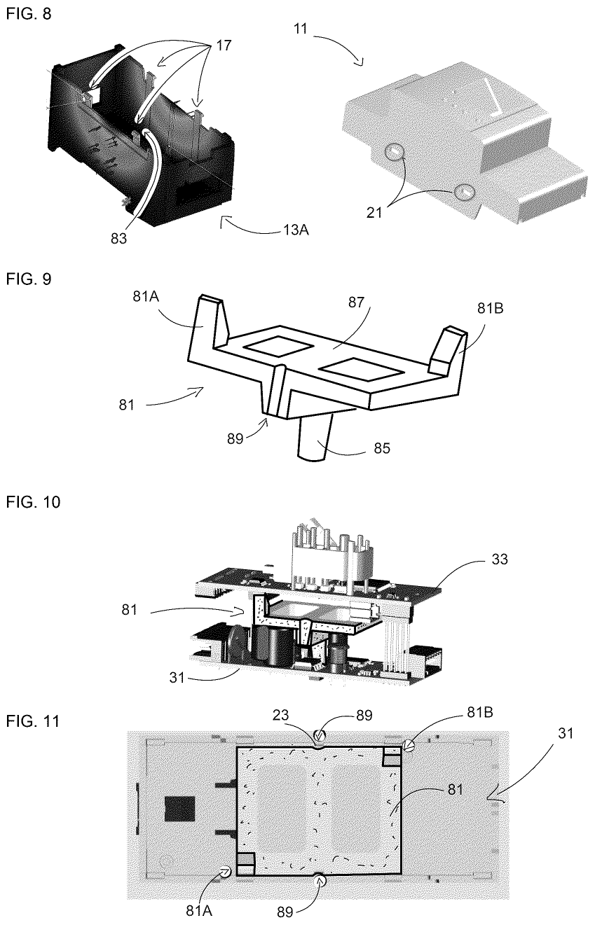

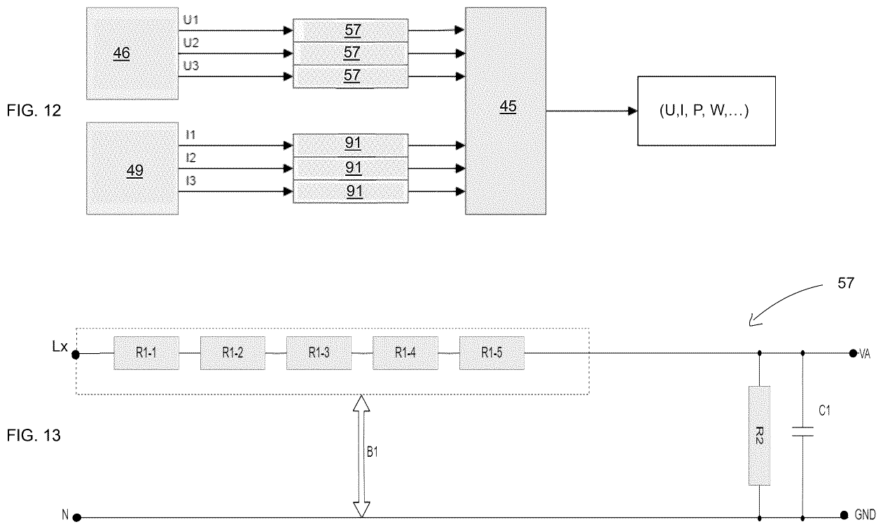

In connection with FIGS. 1 to 7, an exemplary embodiment of an electronic measuring device 1 for measuring electrical quantities (also referred to herein as a measuring device) is described below. In connection with FIGS. 8 to 11, an example of a locking mechanism for a latching housing for, for example, the device 1, generally for an electrical device, is described. Finally, in connection with FIGS. 12 to 15, an exemplary embodiment for a voltage divider for providing voltage values for several measuring chips in, for example, an electrical appliance such as the measuring device 1 is described.

FIG. 1 shows the electronic measuring device 1, which is used, for example, to measure the power of one or more 1-phase or 3-phase consumers/generators. The electronic measuring device 1 is prepared, for example, on the back of a housing 3 for mounting on a top-hat rail (not shown) and has a width B of two division units (approx. 36 mm) and a length L of 100 mm. A LAN socket 5 as well as indicator lights 7 (e. g., LED indicators) and a pushbutton 9 are located on a front side (when the measuring device 1 is mounted, this is the top side of the measuring device 1 facing a user). These serve as user interfaces that indicate the operating status or, for example, enable a reset by the user.

With a view to a possible lined-up arrangement of several devices along a top-hat rail, the measuring device 1 also provides two access sides, which can be provided with corresponding sockets for connecting external current transformers (not shown) or a power supply.

In the exemplary embodiment shown in FIG. 2 in the unassembled state, the measuring device 1 comprises a two-part housing with two shells, referred to herein as upper and lower shells. FIG. 2 shows an upper shell 11 as well as a lower shell 13A and an alternative lower shell 13B. On an access side 16, the lower shell 13A is equipped with an opening 15A for a plug for power measurement, e. g., of a 3-phase consumer. The lower shell 13B is equipped with a larger opening 15B for two plugs, which can be plugged in next to each other and can be used for power measurement for e. g., two 3-phase consumers. The lower shell 13A or 13B also has an opening 15C for a voltage connection.

The housing 3 is formed by assembling the upper shell and the lower shell, whereby the shells are held together by latching hooks 17. In the example, four latching hooks 17 are provided on the lower shells 13A, 13B, two on each longitudinal wall 19 of the lower shells 13A, 13B. In general, a plurality of latching hooks or latching rails can be provided on one shell, which engage in corresponding latching structures on the other shell. In FIG. 2, for example, the latching hooks 17 engage in openings 21 provided in the upper shell 11.

The shells are made of a polyamide (such as ULTRAMID_A3UG5 GREY 32201 POLYAMIDE), for example, and have a wall thickness in the range of, e. g., 0.75 mm to 3 mm. The wall thickness of the shells and in particular the thickness of the latching hooks 17 is configured such that the latching hooks 17 can be bent and latched into the openings 21, in particular for easy assembly of the housing 3.

FIG. 2 also shows guide rails 23, which are provided in the center of the lower shell 13A and 13B on the inside of the longitudinal wall 19, as well as mounting domes 25 in the corners of the housing for screwing on circuit boards. In the example explained below, one circuit board is screwed into the upper shell and one circuit board into the lower shell.

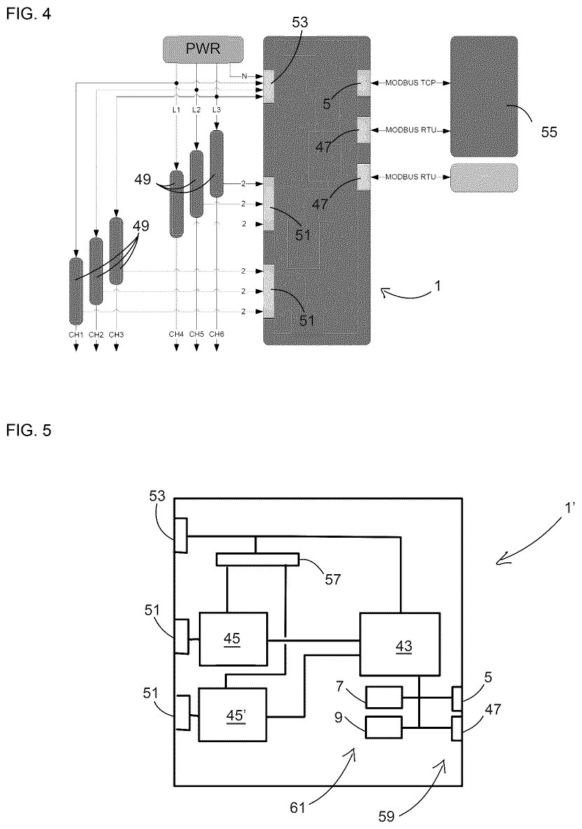

For a phase-specific power measurement, external current transformers (not shown) are connected to the access side 16 (see FIG. 1). In its interior, the measuring device 1 comprises a circuit arrangement that is configured compact due to the small spatial dimensions of the interior space provided by the housing 3. The circuit arrangement is configured to detect the current in the respective phases with the external current transformers. Furthermore, the circuit arrangement is configured to detect the associated (mains) voltage directly via voltage dividers connected to the mains voltage source. Further electrical quantities such as the electrical power P, the electrical apparent power S, the electrical reactive power Q, the mains frequency f etc. can be derived essentially in real time from the values measured in this way for the electrical current I and the electrical voltage U. A time measurement interval on which the measurement is based can be implemented, for example, in the range of 20 ms; furthermore, adjustable measurement intervals can be, for example, 20 ms, 100 ms, 200 ms, 500 ms or 1000 ms. The electrical values determined can then be queried in real time via data interfaces based on Modbus RTU/TCP (LAN (Local Area Network) connector 5) by a Modbus master (e. g., an energy manager) (see also FIG. 4).

FIG. 3 shows an exemplary circuit arrangement 27 of the measuring device 1 shown in FIG. 1 using two assembly units 29A, 29B, which are each implemented with a measuring circuit board 33 and a communication circuit board 31, respectively. Both assembly units 29A, 29B are fixed via the circuit boards in the upper and lower housing shell, e. g., by means of screws or latching hooks. In the assembled state, i. e., when the two housing shells (top, bottom) are latched together, the assembly units 29A, 29B are connected via a two-part plug connector 35.

With reference to FIG. 2, a light guide-plunger-component 37 can use a plurality of light guides to ensure that light emitted by LEDs arranged on the communication circuit board 31 is clearly visible on the device's outside of the upper shell 11. Furthermore, the light guide-plunger-component 37 can comprise an integrated plunger that mechanically couples to a pushbutton on the communication circuit board 31. (See also FIG. 10 for the arrangement of the light guide-plunger-component 37 between the communication circuit board 33 and the upper shell 11.) Thus, a user interface to the communication circuit board 33 can be provided by the pushbutton 9 and by the LEDs—in particular three double LEDs 39 (red/green) for the operating status. In particular, a pushbutton IC 41 (see FIG. 3), which can be actuated with the pushbutton 9, can generate corresponding input signals, depending on the length of the button press. For example, the measuring device 1 can be restarted independently of the software using pushbutton 9.

To implement the measuring function, the device comprises at least two microcontrollers: a master controller (master control unit MCU, for example, a microcontroller STM32F407)—generally referred to herein as data communication chip 43 (see FIG. 3)—and at least one measuring IC (for example, a Metering-IC SY7M166HT)—generally referred to herein as measuring chip 45. The data communication chip 43 is primarily used for data output. Thereby, the data communication chip 43 enables communication with a higher-level system, e. g., via Modbus RTU/TCP, and provides user interaction via the LEDs 39 and the pushbutton 9. Starting from the data communication chip 43, a network connection via TCP (LAN socket 5) and a serial RS485 BUS connection (RTU terminal 47) can be provided, for example.

FIG. 4 schematically illustrates an exemplary integration of the measuring device 1 in an overall system for monitoring six channels CH1, CH2, . . . . CH6. Corresponding measurements to determine electrical quantities are performed using six current transformers (current transformer CT) 49, which are connected to CT connections 51 (each with two input pins). The measuring device 1 is powered, for example, via a serial RS485 bus connection, mains voltage 46 (voltage inputs L1, L2, L3 of the outer conductors, N of the neutral conductor), whereby the supply voltage is fed to the measuring device 1 via a voltage connection 53. For example, the internal electronics are subject to an internal supply via the voltage inputs L1 and N. Via Modbus TCP or RTU (one LAN socket 5, two RTU terminals 47), an energy manager 55 can read in the values determined with the measuring device 1 or a user can carry out a configuration of the measuring device 1.

FIG. 5 illustrates an exemplary circuit arrangement 1′ for the measuring device 1 in a schematic block diagram of the various components. The circuit arrangement 1′ comprises the voltage connection 53, a voltage divider 57 electrically connected to the voltage connection, at least one CT connection 51 for connecting at least one external current transformer 49 (for example, one or two CT connections), the first measuring chip 45 electrically connected to the voltage divider 57 and the (first) CT connection 51 for determining electrical quantities (measurement of the current for the connected current transformer and the associated voltage) and outputting the electrical quantities (measurement data and data derived therefrom) to the data communication chip 43 of the circuit arrangement 1′, the data communication chip 43 being in particular galvanically isolated from the first measuring chip 45. The circuit arrangement 1′ can further comprise at least one data connection 59 (e. g., LAN socket 5 and/or RTU terminals 47) electrically connected to the data communication chip 43 and at least one user interface 61 (e. g., indicator light 7 or pushbutton 9) electrically connected to the data communication chip.

FIG. 5 optionally shows a further (second) measuring chip 45′ which, like measuring chip 45, is configured to determine electrical quantities and output the electrical quantities (measurement data and quantities derived therefrom) to the data communication chip 43 and is integrated into the circuit arrangement 1′ (e. g., under galvanic isolation from the data communication chip 43). In particular, a voltage divider can be used for this purpose, as explained in connection with FIGS. 12 to 15.

The measuring chip 45 can, e. g., be configured as a dedicated measuring IC for current, voltage, power and energy measurement in order to implement the measurements and the calculation of the measured values and to be able to transfer the latter to the data communication chip 43. Up to three current transformers, e. g., can be connected to each measuring chip 45.

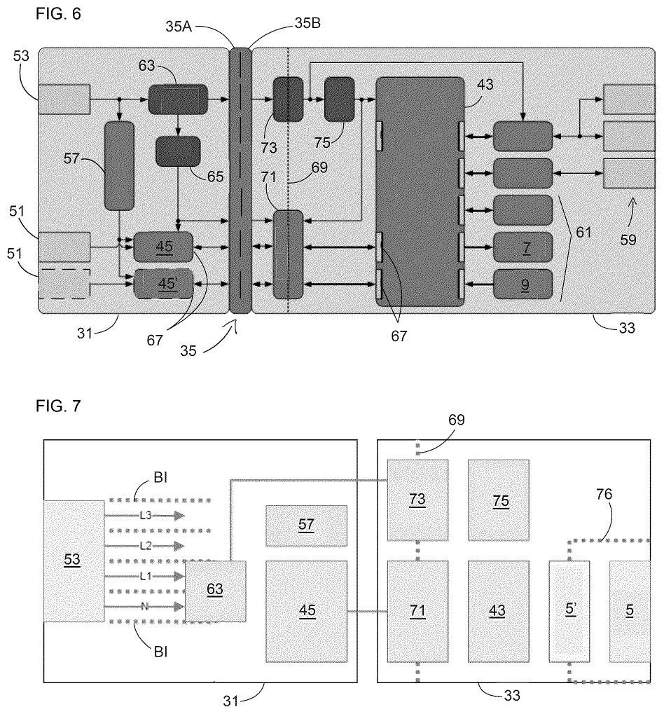

FIG. 6 schematically illustrates the distribution of the circuit arrangement I′ on the measuring circuit board 31 and the communication circuit board 33. The measuring circuit board 31 is equipped, e.g., with the voltage connection 53, the voltage divider 57, the CT connection 51 (optionally two or more CT connections). Furthermore, the measuring circuit board 31 has the (first) measuring chip 45 and optionally the second or further measuring chips 45′, each of which is electrically connected to the associated CT connection 51 and the voltage divider 57. A first part 35A of the plug connector 35 is provided for electrical contacting the communication circuit board 33 (electrical plug connection).

The power supply can further have an AC/DC power supply 63 and a linear regulator 65 to provide the DC voltage for the measuring chip or chips 45, 45′.

The communication circuit board 33 is equipped, e.g., with the second part 35B of the plug connector 35, the data communication chip 43, which is electrically connected via the plug connection to receive the measurement data from the first measuring chip 45, data connection(s) 59 and user interface(s) 61.

For the internal communication between data communication chip 43 and measuring chip 45, a UART interface 67 with an internal communication protocol for the measurement application can be used, for example. As the measuring chip 45 is in the primary circuit (i. e., voltages in the range of several 100 V may be present), it is necessary to galvanically isolate the data communication chip 43 from the measuring chip 45, 45′, exemplarily from the UART interface 67 (see FIG. 5). In the present embodiment, a reinforced isolation 69 (schematically illustrated as a dashed line) is implemented spatially on the communication circuit board 33. With regard to the data exchange, this is achieved, for example, by a galvanic isolator 71 and, with regard to the power supply, optionally by an (e. g., insulated) DC/DC isolator 73. In other words, the measuring chip 45 is at N potential, which is regarded as mains potential, so that reinforced isolation from the data communication chip 43 and the interfaces (Ethernet, RS485) is necessary. This is implemented (according to some embodiments of the invention) on the communication circuit board 33 in the present exemplary embodiment.

Further DC/DC converters 75 can be provided on the communication circuit board 33 for the power supply of the data communication chip 43.

As shown in FIG. 7, the measuring device 1 uses an external input voltage (e.g., lines L, N) to supply the measuring chip(s) 45 and the data communication chip 43. The mains voltage is converted by the AC/DC power supply unit 63 into a voltage, e. g., in the range of less than 10 VDC, and passed on to the measuring chip(s) 45 via the linear regulator 65 (further voltage adjustment and active filtering of the voltage signal) (see FIG. 6). The voltage is transmitted to the secondary side, in this case the components for communication, via the (insulated) DC/DC isolator 73 arranged on the communication circuit board 33, and supplies, for example, the RS-485 transceiver directly or, additionally regulated by a DC/DC converter 75, the other peripheral components such as the data communication chip 43 with, e. g., 3.3 VDC.

The AC/DC power supply unit 63 is therefore electrically connected to the voltage connection on the one hand. On the other hand, it is electrically connected to the measuring chips 45, 45′ via the linear regulator 65 to supply power to the first/second measuring chip 45, 45′. To supply power to the data communication chip 43, the AC/DC power supply unit 63 is also electrically connected—in a galvanically isolated manner and in particular via the DC/DC converter 75 for voltage reduction—to the data communication chip via the electrical plug connection 35 and the DC/DC isolator 73 arranged on the communication circuit board 33.

FIG. 7 summarizes the isolation concepts exemplarily and schematically illustrates, on the measuring circuit board 31, a basic isolation BI between the outer/neutral conductors/phases. The reinforced isolation 69 already explained is implemented on the communication circuit board 33, as is an isolation 76 to the Ethernet.

In addition to supplying the components of the circuit arrangement, the measuring device 1 also uses the input voltage to measure the voltage that is to be assigned to a current measurement with the current transformer 49. Sufficient dielectric strength between conductors L1, L2, . . . and neutral conductor N is required for the voltage measurement. This is achieved with the help of the voltage divider 57. The voltage divider 57 comprises preferably cost-effective a series connection of several, e. g., five, standard resistors of several 100 kΩ each. With two or more measuring ICs, the voltage divider is preferably adapted in order to avoid or reduce a mutual interference between the analog digital converter ADCs of the measuring chips. In particular, a low-pass function can be provided between the last resistor and the connection pin of the measuring chip so that, e. g., a terminating capacitor is located preferably directly at the connection pin of the measuring chip. See also the illustrations for FIGS. 12 to 15.

A further aspect disclosed herein and in particular in connection with FIGS. 8 to 11 relates to preventing or at least making it more difficult to open a housing consisting of two housing shells that are connected by means of a latching connection. In particular, a reinforcing element, referred to herein as formed component 81, is provided in an interior 83 of the housing 3 for this purpose, which additionally locks the latching connection.

As illustrated by arrows in FIG. 8, the housing 3, in particular, the lower shell 13A, can be deformed by forces acting on the side walls in such a way that the latching hooks 17 of the lower shell 13A move inwards and are thus moved out of the latched position in the case of a latching connection as explained in connection with FIG. 2. If, in the case shown, the latching hooks 17 no longer engage in the openings 21 of the upper shell 11 (of the other housing part), the housing 3 can be opened.

In order to prevent or at least make it more difficult for the latching connection to disengage, a greater wall thickness can be provided in prior art housings, whereby the lateral forces are absorbed by the housing and deformation of the housing is prevented, or a latching hook can be inserted in a flap and thus held on both sides, which prevents disengagement.

Both of the aforementioned approaches reduce the interior space available for electronics in the housing. In particular, the provision of a flap can locally restrict a rectangular basic shape available in the interior for a circuit board, so that a smaller circuit board or a local revision of the shape of the circuit board is required. In addition, the shaping of the housing becomes more complex due to the design of the flap, which is particularly disadvantageous for small electronic devices such as top-hat rail devices in terms of keeping costs low.

In some embodiments, a formed component is now positioned in a housing of an electrical appliance, which forms one or more counterholders—referred to herein as blocking elements—for absorbing lateral compressive forces in the housing's interior 83 on the latching hooks 17. The support of the latching hooks 17 by the counterholders from the inside additionally prevents opening by means of a tool with which the latching hooks can be pressed inwards. Thereby, disengagement can be made at least more difficult and, if possible, the housing shells can be prevented from coming loose.

FIG. 9 shows an exemplary formed component 81, which is adapted to the two-part housing of FIG. 2 or FIG. 8 and supports the latching hooks 17 in the assembled state, in particular restricts, preferably prevents, an inward movement of the latching hooks. The formed component 81 forms two diagonally arranged blocking elements 81A, 81B in the “upper area”. In the assembled state, the blocking elements 81A, 81B are configured and arranged to each form a latching hook 17 in such a way that a disengagement of the latching connection, in particular a deformation of the latching hook 17 in the direction of a housing interior 83, is counteracted. This configuration is exemplarily directed to a latching connection, which has latching hooks 17 arranged on opposite sides of a housing. The formed component 81 is exemplarily configured in this case such that it counteracts disengagement of at least one of the latching hooks 17 on each side of the housing 3.

In addition, the formed component can act as a spacer and ensure the presence of a guaranteed minimum distance—a safety distance. FIG. 10 illustrates this for an exemplary implementation of an electrical device—here an embodiment of the measuring device—with two circuit boards arranged offset to each other. The formed component 81 is configured such that it provides in the assembled state a minimum distance between the circuit boards, in this case the measuring circuit board 31 and the communication circuit board 33. The formed component 81 ensures the minimum distance, in particular, even if the (screw) connection of one or both of the circuit boards to the respective shell fails. For example, the formed component 81 comprises at least one stand 85, which is arranged in particular in the assembled state in a non-equipped area of the measuring circuit board 31 and whose length determines in particular a position of the at least one blocking element 81A, 81B in the housing interior 83, and in particular the minimum distance between the circuit boards.

The inherent safety distance can provide additional protection in case of high voltage in the housing 3. For example, a height of the counterholder 81A, 81B can be configured so high that the formed component 81 touches a, for example the upper, circuit board. For support, the stand 85 can rest on the other circuit board in a free area. The formed component 81 can thus additionally ensure that both circuit boards have a guaranteed minimum distance and that air gaps between boards with different voltages are ensured even if the screw connections or the mounting domes 25 fail.

Furthermore, FIG. 9 shows a flat-shaped structural section 87 of the formed component, which positions the blocking elements 81A, 81B spatially relative to the latching hooks 17 assigned to them. Preferably, the blocking elements 81A, 81B are also arranged in a non-equipped area of the communication circuit board 33 in the assembled state.

Preferably, the formed component 81 is made of a sufficiently electrically insulating material.

Preferably, the formed component can be guided and positioned along a groove in the housing and thus, for example, not allow any movement of the formed component transverse to the direction of the groove. For example, the formed component 81 and at least one of the shells can form a guide system that is configured to position the formed component 81 during assembly of the measuring device 1 and/or to hold the formed component 81 in the assembled state. In particular, the guide system can comprise a guide rail 23, in particular, a groove, on an inner wall of one of the shells or on the formed component 81 and a counterpart 89 engaging in the guide rail 23, in particular, in the groove, on the formed component 81 or on the inner wall of one of the shells.

Depending on the equipment of the circuit boards, the geometry of the formed component 81 can generally be configured such that the installation space between the two circuit boards is only slightly reduced or, if possible, not adversely restricted.

The formed component 81 can be inserted if required (opening no longer possible) or omitted (access to the inside of the housing remains permitted with a tool). In other words, depending on whether increased opening protection is required in a sales area, the formed component 81 can be used or not. In particular, requirements of UL2808/UL 61010-1, for example, can be fulfilled by using the formed component 81.

Advantages compared to housings with larger wall thickness are a better utilization of the internal installation space, which is made possible by the low wall thickness of the housing. Furthermore, the housing can no longer be “deformed” due to the absorption of lateral compressive forces by the formed component.

Advantages compared to the solution using latching hooks in flaps are a support of the latching hooks by the separate modular formed component, so that the latching hooks can no longer be disengaged, a simpler design of the housing without flaps and the gain in installation space on the assembly by dispensing with the flaps.

With regard to a further concept according to this disclosure, an electronic circuit for dividing and filtering, referred to herein as a voltage divider, is described in connection with FIGS. 12 to 15. In particular, this aspect relates to a concept for a space-saving circuit for measuring mains voltages for two or more measuring chips 45, 45′. To measure, e. g., the active power of an alternating voltage consumer, the voltage and current must be measured synchronously and the effective values calculated in real time. Commercial measuring ICs are used for this, which usually have a maximum of 3 voltage inputs and 3 (max. 4) current inputs.

FIG. 12 shows an exemplary circuit of a measuring chip 45 with three inputs for voltage U1, U2, U3 (derived from the mains voltage 46) and three inputs for current I1, I2, I3 (output by measuring coils). To provide voltage for the measuring chip 45, a separate voltage divider 57 is used for each outer conductor (phase), which divides the mains voltage down so that it can be processed by an AD converter in the measuring chip 45, for example. The measuring currents are fed to the measuring chip 45 via, e. g., an input circuit 91, respectively. As part of a synchronous analog-to-digital conversion of the current and voltage values, measured values U, I, P, W, . . . are derived from the current and voltage values in the measuring chip 45. This enables real-time calculation of the effective value for current, voltage, power, energy etc. for all three phases of a consumer or generator. The measured values are then made available via the device's interfaces.

As shown in FIG. 13 for an exemplary outer conductor (voltage input Lx, e. g., L1, L2 or L3), the voltage dividers 57 can, for example, consist of a series connection of standard resistors R1-1, R1-2 . . . . R1-5—generally R1-n—with a total resistance R1 of the series connection (in the range of 1 . . . 10 MΩ), because the dielectric strength of a single resistor is limited in each case. Based on a dielectric strength of the standard resistors of approx. 200 V each, the example of five resistors results in a dielectric strength of the resistor series of 5×200 V=1000 V. The use of special high-voltage resistors is usually avoided, as these are significantly more expensive and often have poorer properties in terms of temperature coefficient, accuracy and drift.

A terminating circuit consisting of a resistor R2 (in the range of 100Ω . . . 5 kΩ) and a capacitor C2 (in the range of 500 pF . . . 10 nF) can be formed between the outer conductor and the neutral conductor N.

R1, R2 and C1 can in particular form an RC filter as a low-pass filter. The circuit is selected, for example, such that the cut-off frequency of the low-pass filter is sufficiently high and so that the low-pass filter has a negligible attenuation at the use frequency of, e. g., 50/60 Hz including five harmonics and at the same time attenuates sufficiently strongly at the sampling rate (aliasing filter). Thereby, the capacitor C1 should not be too large, as otherwise the voltage divider R1/R2 could be loaded depending on the frequency. Moreover, the capacitor C1 can preferably be configured as a buffer for the input.

Furthermore, a necessary basic isolation B1 is indicated in FIG. 13 that prevents breakdown between the resistors of the series connection and the neutral conductor N in the event of transient over-voltages.

The voltage divider (R1/R2) reduces the input voltage from, e. g., 230 V to voltages of less than 1 V, which are present at the connections VA and GND for connecting to the measuring chip 45.

As already mentioned in the previously described embodiments of the measuring device 1, there are application scenarios in which more than three single-phase loads or more than one three-phase load or generator need to be measured, so that two or more measuring chips can also preferably be used in one measuring device 1.

A circuit structure, in which a series connection as shown in FIG. 13 is used together, does not represent any or at least a disadvantageous implementation for voltage division, because the channels CH1.ADC and CH2.ADC of, for example, two non-synchronized measuring chips influence each other during the measuring process and closing/opening of a switch during the sampling process.

Furthermore, the structure of the series circuit shown in FIG. 13 could be duplicated and generally used for each measuring chip. Although the voltage connection 53 could be used jointly for the voltage, each of the voltage dividers to the neutral conductor N would have to be configured in basic isolated manner. This requires more space and would also have the disadvantage of essentially doubling the number of components.

The embodiments of the present disclosure for the voltage divider 57 explained below results in a reduction in the space required and a smaller number of components-compared to duplication.

A corresponding measuring device thus has a voltage divider 57 for outputting reduced voltages to at least two measuring chips 45, 45′ for measuring electrical quantities by means of two external current transformers 49 connected to the respective measuring chips 45, 45′.

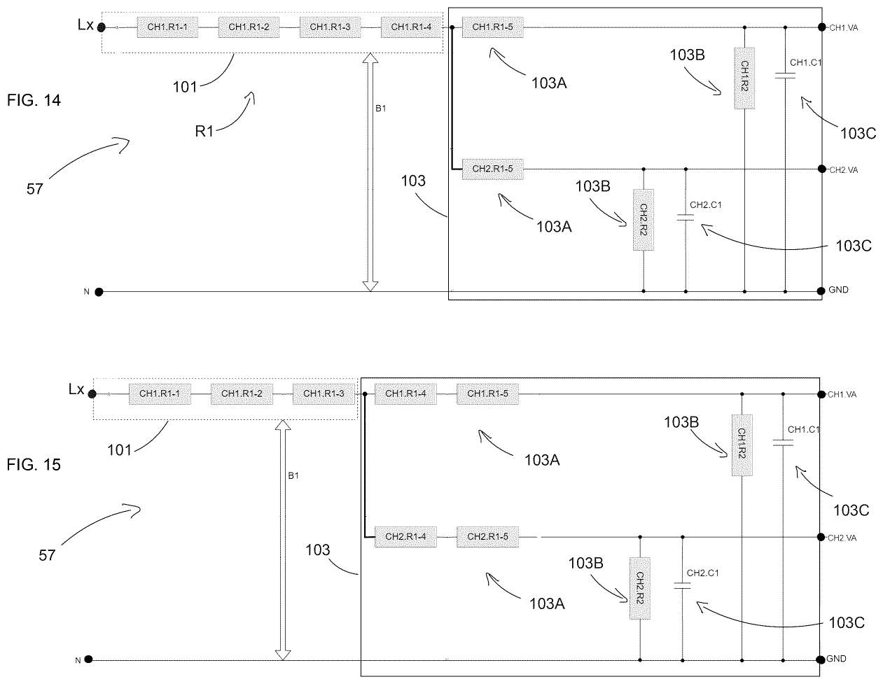

In general, the voltage divider 57 can output voltages to the first measuring chip 45 and the second measuring chip 45, wherein it receives the input voltage from the voltage connection 53 at a voltage input Lx and outputs a reduced voltage for each of the measuring chips 45, 45′ at a voltage output CH1-VA, CH2-VA. The voltage divider 57 comprises two (or more) independent, decoupled outputs, in particular for a voltage division with low-pass function. The exemplary circuit structure of the voltage divider 57 in FIG. 14 shows a resistor series section 101 electrically connected to the voltage input Lx. The resistor series section 101 comprises several series-connected resistors R1-1, R1-2 . . . , R1-4, which contribute to the voltage drop for each of the measuring chips 45, 45′/voltage outputs. Furthermore, FIG. 14 shows a parallel circuit section 103 electrically connected to a last resistor R1-4 of the resistors of the resistor series section 101. The parallel circuit section 103 comprises, for each voltage output CH1.VA, CH2.VA, a first resistor section 103A (In the example of FIG. 14, this is a resistor CH1.R1-5, CH2.R1-5.) extending the series-connected resistors of the resistor series section 101 and electrically connected to a respective voltage output CH1.VA, CH2.VA, a second resistor section 103B (In the example of FIG. 14, this is a resistor CH1.R2, CH2.R2.) electrically connecting the respective voltage output CH1.VA, CH2.VA and the neutral conductor N, and a capacitor section 103C (In the example of FIG. 14, this is a capacitor CH1.C1, CH2.C1.) electrically connecting the respective voltage output CH1.VA, CH2.VA and the neutral conductor N.

Within embodiments of this inventive concept, only the first resistors CH1.R1-1 . . . . CH1.R1-4 are used for both measuring chips 45, 45′, i. e., for both measuring channels CH1, CH2 to an outer conductor (phase). For a voltage input Lx (e. g., L1, L2 or L3), FIG. 14 shows an exemplary setup of a voltage divider 57 used jointly for two measuring ICs, in which voltage divider 57 the last resistor of the series connection from FIG. 13 is duplicated-here the resistors CH1.R1-5, CH2.R1-5. The series circuit of the resistors CH1.R1-1, . . . . CH1.R1-4 is electrically connected in a parallel circuit via one of the resistors CH1.R1-5, CH2.R1-5 to the connection CH1. VA for the measuring chip 45 and the connection CH2. VA for the measuring chip 45′. For the voltage divider 57 having comparable properties compared with FIG. 13, the resistance values of CH1.R1-1 . . . . CH1.R1-4 can preferably be halved, because the resistors and capacitors CH1.R2, CH1.C1 and CH2.R2, CH1.C1 also form part of the parallel circuit.

The voltage divider 57 reduces the input voltage-usually in a range of 200 V to 1000 V—to a measurement voltage range—usually less than 3 V. For example, the resistors of the resistor series section 101 can form a total resistance R1 in a range from 500 kΩ to 1 MΩ. Together with the resistors CH1.R2, CH2.R2 of the respective R/C element 105 in a range from 100Ω to 10 kΩ, the required voltage division is achieved. At the same time, the the series-connected resistors of the resistor series section 101 extending resistors CH1.R1-5, CH2.R1-5 of the parallel circuit section 103 can provide sufficient decoupling between the voltage outputs CH1.VA, CH2.VA.

FIG. 15 shows a further exemplary setup of a voltage divider 57 used jointly for two measuring chips, in which setup the last two resistors CH1.R1-4 and CH1.R1-5 of the series circuit 101 of FIG. 12 are implemented twice and each form the resistor section 103A for the voltage outputs CH1.VA, CH2.VA, whereby the influence of the two channels at the connections CH1.VA and CH2. VA can be further reduced. Thus, one sees in FIG. 15 that the tap for the parallel circuit section 103 already takes place between CH1.R1-3 and CH1.R1-4. In this case-compared to FIG. 14—an additional resistor CH2.R1-4 is required in the circuit arrangement; a basic isolation to the parallel circuit section 103 becomes larger, as the voltages at the input to the resistors CH1.R1-4 and CH2.R1-4 of the resistor sections 103A are increased.

Specifically, FIG. 15 shows a voltage divider having a voltage input Lx for receiving a line voltage, a voltage output CH1-VA, CH2-VA for each of at least two measuring chips 45, 45′ for outputting a reduced voltage to one of the at least two measuring chips 45, 45′, a resistor series section 101 electrically connected to the voltage input Lx and comprising a plurality of series-connected resistors R1-1, R1-2 . . . , R1-3, which contribute to the voltage drop for each of the at least two measuring chips 45, 45′, and a parallel circuit section 103 electrically connected to a last resistor R1-3 of the resistors of the resistor series section 101.

The parallel circuit section 103 comprises, for each of the at least two measuring chips 45, 45′, two series-connected resistors CH1.R1-4, CH1.R1-5 or CH2.R1-4, CH2.R1-5 extending the series-connected resistors of the resistor series section 101 and electrically connected to a respective voltage output CH1.VA, CH2.VA.

As described in connection with FIG. 14, the parallel circuit section 103 shown in FIG. 15 comprises, for each voltage output CH1.VA, CH2.VA, a resistor CH1.R2, CH2.R2 electrically connecting the respective voltage output CH1.VA, CH2.VA and a neutral conductor N, and a capacitor CH1.C1, CH2.C1 electrically connecting the respective voltage output CH1.VA, CH2.VA and the neutral conductor N.

In the case of measuring devices for active power and active energy with more than three current inputs, advantages of the voltage divider include a predominantly combined use of the components for both voltage divisions and in particular a joint use of resistors R1-1 to R1-4 in the embodiment of FIG. 14 and resistors R1-1 to R1-3 in the embodiment of FIG. 15. Due to the fewer components required, this leads to a smaller space requirement on the measuring circuit board, whereby there are enabled small measuring devices or measuring devices, which can measure several consumers, for example. In general, this results in more cost-effective measuring devices.

It will be recognized that the number and the resistance values of the resistors in the resistor series section 101 and in the parallel circuit section 103, in particular in series circuits of the first and/or second resistor section, can be selected for the voltage drop required in a respective case.

It is explicitly emphasized that all features disclosed in the description and/or claims are to be considered separate and independent from each other for the purpose of the original disclosure as well as for the purpose of limiting the claimed invention(s), regardless of the combinations of features in the embodiments and/or claims. It is explicitly stated that all range indications or indications of groups of units disclose any possible intermediate value or subgroup of units for the purpose of the original disclosure as well as for the purpose of limiting the claimed invention(s), in particular also as the limit of a range indication.

What is claimed is:

1. A measuring device for electrical quantities comprising:
a housing,
a measuring circuit board and a communication circuit board, which are arranged offset on top of each other in the housing,
wherein the measuring circuit board is equipped with
a voltage connection,
a voltage divider electrically connected to the voltage connection,
at least one first CT connection for connecting at least one external current transformer,
a first measuring chip, which is electrically connected to the voltage divider and the first CT connection, for determining the electrical quantities and for outputting the electrical quantities as measurement data to a first part of a plug connector, and
wherein the communication circuit board is equipped with
a second part of the plug connector, which, together with the first part, causes an electrical plug connection between the communication circuit board and the measuring circuit board,
a data communication chip, which is electrically connected to the second part and galvanically isolated in order to receive the measurement data from the first measuring chip, wherein a galvanic isolation is provided between the first measuring chip and the data communication chip on the communication circuit board,
at least one data connection electrically connected to the data communication chip, and
at least one user interface electrically connected to the data communication chip.

2. The measuring device of claim 1, wherein the measuring circuit board is further equipped with an AC/DC power supply unit that:
is electrically connected to the voltage connection,
for supplying voltage to the first measuring chip, is electrically connected to the first measuring chip, in particular via a linear regulator, and
for supplying power to the data communication chip, is electrically connected to the data communication chip in a galvanically isolated manner via the electrical plug connection and a DC isolation element arranged on the communication circuit board, in particular via a DC/DC element for voltage reduction.

3. The measuring device of claim 1, wherein:
the at least one data connection comprises an Ethernet connection and/or an RS485 connection, and/or
the at least one user interface comprises an LED display and/or a pushbutton.

4. The measuring device of claim 1, wherein the housing comprises a first shell and a second shell as a two-part housing, wherein the measuring circuit board is mounted in the first shell and the communication circuit board is mounted in the second shell, in particular in each case via a screw connection, and
wherein the plug connection is caused in particular by assembling the first shell and the second shell to form the housing.

5. The measuring device of claim 4, wherein the housing:
has a latching connection for mechanically connecting the first shell to the second shell, and/or
has openings, in particular in the first shell, for the voltage connection and/or the at least one first CT connection, and/or openings, in particular in the second shell, for the at least one data connection and the at least one user interface, the user interface being made accessible to a user in particular via a light guide and/or plunger element arranged between the communication circuit board and the second shell.

6. The measuring device of claim 1, wherein the housing comprises a first shell and a second shell as a two-part housing and has a latching connection for mechanically connecting the first shell to the second shell, wherein the latching connection is formed by at least one latching hook and at least one latching region, in particular an opening, on respectively the first shell and the second shell, wherein
the measuring device further comprises a formed component arranged between the measuring circuit board and the communication circuit board and the formed component having at least one blocking element, the at least one blocking element being arranged in the assembled state with respect to a latching hook such that a disengagement of the latching connection, in particular deformation of the associated latching hook in the direction of an interior of the housing, is counteracted, and in particular a disengagement is prevented.

7. The measuring device of claim 6, wherein the latching connection has latching hooks arranged on opposite sides of the housing and the formed component is configured such that it counteracts a disengagement of at least one of the latching hooks on each side of the housing.

8. The measuring device of claim 6, wherein the formed component is configured such that, in the assembled state, the formed component provides, and in particular ensures, a minimum distance between the measuring circuit board and the communication circuit board, wherein the minimum distance in particular ensures the minimum distance even if one or both of the measuring circuit board and the communication circuit board are not connected to the respective first and second shell, and/or
wherein the formed component is made of an electrically insulating material.

9. The measuring device of claim 6, wherein the formed component comprises
at least one stand, which is arranged in particular in the assembled state in a non-equipped region of the measuring circuit board and the length of which determines in particular a position of the at least one blocking element inside the housing, and in particular the minimum distance between the measuring circuit board and the communication circuit board, and/or
a flat-shaped structural section, which positions the at least one blocking element spatially relative to the at least one latching hook, and/or
wherein the at least one blocking element is arranged in the assembled state in a non-equipped region of the communication circuit board.

10. The measuring device of claim 6, wherein the formed component and at least one of the first shell and the second shell form a guide system that is configured for positioning the formed component during assembly of the measuring device and/or for holding the formed component in the assembled state,
wherein the guide system comprises in particular a guide rail, in particular a groove, on an inner wall of one of the first shell and the second shell or on the formed component and a slide element respectively engaging in the guide rail, in particular in the groove, on the formed component or on the inner wall of one of the first shell and the second shell.

11. The measuring device of claim 1, wherein the voltage divider is configured to output reduced voltages to at least two measuring chips for the measurement of electrical quantities by two external current transformers connected to the respective measuring chips, and wherein the voltage divider comprises:
a voltage input, in particular for receiving a mains voltage,
for each of the at least two measuring chips, a voltage output for supplying one of the reduced voltages to one of the at least two measuring chips,
a resistor series section electrically connected to the voltage input and comprising a plurality of series-connected resistors contributing to the voltage drop for each of the at least two measuring chips, and
comprising a parallel circuit section electrically connected to a last resistor of the resistors of the resistor series section,
for each of the at least two measuring chips, a resistor extending the series-connected resistors of the resistor series section and electrically connected to a respective voltage output,
for each voltage output, a resistor electrically connecting the respective voltage output and a neutral conductor, and a capacitor electrically connecting the respective voltage output and the neutral conductor.

12. The measuring device of claim 11, wherein the measuring circuit board is equipped with
a second CT connection for connecting at least one external current transformer and
a second measuring chip electrically connected to the voltage divider and the second CT connection for determining the electrical quantities and outputting the electrical quantities to the communication circuit board as measurement data for the at least one external current transformer connected to the second CT connection, and
wherein the first measuring chip is electrically connected to a first voltage output and the second measuring chip is electrically connected to a second voltage output.

13. The measuring device of claim 11, wherein the voltage divider is configured for reducing an input voltage in a range from 200 V to 1000 V into a measuring voltage range in a range from 0 V to 3 V, and/or
wherein the resistors, which extend the series-connected resistors of the resistor series section, between the respective voltage output and the neutral conductor cause a decoupling between the voltage outputs.

14. The measuring device of claim 11, wherein the resistors of the resistor series section form a total resistance in a range from 500 kΩ to 10 MΩ, and/or the parallel circuit section forms a resistance in a range from 100Ω to 10 kΩ, so that together with the resistor between the respective voltage output and the neutral conductor a voltage division is implemented at the respective voltage output, and/or
wherein for the respective voltage output, the resistors of the resistor series section and the resistor between the respective voltage output and the neutral conductor form an RC low-pass function with the capacitor between the respective voltage output and the neutral conductor, and/or
whereby the capacitor between the respective voltage output and the neutral conductor forms a buffer function for the respective voltage output.

15. An electrical device, in particular for measuring electrical quantities, comprising an electrical circuit arrangement, in particular for determining and outputting the electrical quantaties, the electrical circuit arrangement comprising a voltage connection and at least one user interface and being arranged in a housing, the housing comprising a first shell and a second shell as a two-part housing and having a latching connection for mechanically connecting the first shell to the second shell, wherein the latching connection is formed by at least one latching hook and at least one latching region on correspondingly the first shell and the second shell,
wherein the electrical device further comprises a formed component arranged in the housing, the formed component configured as at least one blocking element that, in the assembled state, is arranged relative to the latching hook such that a disengagement of the latching connection, in particular deformation of the latching hook in the direction of an interior of the housing, is counteracted.

16. A measuring device for electrical quantities comprising
an electrical circuit arrangement, the electrical circuit arrangement comprising:
a voltage connection,
a voltage divider electrically connected to the voltage connection,
a first CT connection for connecting at least one external current transformer and a second CT connection for connecting at least one external current transformer,
a first measuring chip electrically connected to the voltage divider and the first CT connection for determining and outputting the electrical quantities as measurement data for the at least one external current transformer connected to the first CT connection,
a second measuring chip electrically connected to the voltage divider and the second CT connection for determining and outputting the electrical quantities as measurement data for the at least one external current transformer connected to the second CT connection,
a data communication chip, is configured to receive, process, and output the measurement data from the first measuring chip and from the second measuring chip, and
wherein the voltage divider is configured to output voltages to the first measuring chip and the second measuring chip and comprises:
a voltage input for receiving an input voltage from the voltage connection,
for each of the measuring chips, a voltage output for outputting a reduced voltage to the respective measuring chip,
a resistor series section electrically connected to the voltage input and comprising a plurality of series-connected resistors contributing to the voltage drop for each of the measuring chips, and
a parallel circuit section electrically connected to a last resistor of the resistors of the resistor series section and comprising, for each voltage output,
a first resistor section comprising at least one resistor, the first resistor section extending the series-connected resistors of the resistor series section and being electrically connected to a respective voltage output,
a second resistor section comprising at least one resistor, the second resistor section electrically connecting the respective voltage output and a neutral conductor, and
a capacitor section comprising at least one capacitor, the capacitor section electrically connecting the respective voltage output and the neutral conductor.

17. The measuring device of claim 16, further comprising a further CT connection for connecting a further external current transformer and a further measuring chip, and
wherein the parallel circuit section further comprises, for a further voltage output associated with the further measuring chip, a further first resistor section, a further second resistor section and a further capacitor section.
